(19) United States
(12) Patent Application Publication
(10) Pub. No.: US 2004/0212966 A1
(43) Pub. Date: Oct. 28, 2004

(54) Integral computer connector cover

(76) Inventors: Ken Scott Fisher, Los Angeles, CA (US); Kevin Cotton Baxter, Santa Clarita, CA (US)

Correspondence Address: KEN FISHER, 5521 CLEON AVE., NORTH HOLLYWOOD, CA, 91601, US

(21) Appl. No.: 10/065,942

(22) Filed: Dec. 2, 2002

(51) Int. Cl. H05K 7/16

(52) U.S. Cl. 361/726

(57) ABSTRACT

A portable external computer device having a connector for a standard computer interface and a integral cover, comprising, in a preferred embodiment, a USB-based mass storage memory device, and an “integrated” cover for the USB connector portion; such that the cover is automatically retractable so as to expose the connector for connection to a host computer.

### BACKGROUND OF INVENTION

The present invention pertains generally to external computer devices. More particularly, but not by way of limitation, the present invention relates to a method and apparatus for an integrated cover for a USB flash memory drive.

The world is quickly moving towards truly “standardized” interfaces (e.g., USB 1.1 and 2.0, IEEE-1394 bus a.k.a. Firewire, etc.), which are available now on many systems and platforms (e.g., Apple (tm), PC compatible, etc.). These new unified standards are providing considerably more options to system designers and computer programmers to design more workable “plug and play” external computer devices.

The following related USB prior art is hereby disclosed: U.S. patent application 20020076962 (the '962 patent) Williams, entitled “Secure USB port and connector for wearable and portable computers”, U.S. Pat. No. 6,456,500 (the '500 patent), Chen, entitled “Assembling structure for portable memory device” and U.S. Pat. No. 6,308,215 (the '215 patent) Kolbet, et al, entitled “Extender apparatus for USB connection of computer units”, all of which are hereby incorporated herein by reference, in their entirety.

USB, of course, is well known in the art, and today USB is enjoying tremendous success in the marketplace, with most peripheral vendors around the globe developing products to this specification. Virtually all new personal computers come with one or more USB ports on the box. In fact, USB has become a key enabler of the Easy PC Initiative, an industry initiative led by the Intel Corporation(tm) and the Microsoft Corporation (tm) to make PCs easier to use. This effort sprung from the recognition that users need simpler, easier to use PCs that don't sacrifice connectivity or expandability. USB is one of the key technologies used to provide this. The invention as will be described herein aims to further extend this easier to use, increased connectivity, technology.

Recently, a new class of ultra-portable drives has been introduced to better address the transfer of data from one computer to another. These new ultra-portable devices (e.g., USB mass storage flash drive) are commonly the size of a pack of gum, and have achieved the status of “pocketability” (e.g., easily fits in one's pocket). One such manufacturer is EasyDisk USA, of Norcross, Ga., www.easydisk.com. A device as such, can fit on the end of a user's key chain, and can easily be plugged directly into “multiple” computer systems. This is especially true with Windows (tm) Millennium edition, and higher, operating systems, where devices such as USB flash drives can be plugged into a USB port and used in a “plug and play” fashion (without the need for any external drivers, or data/power cables). Earlier operating systems can also benefit by the addition of a once-installed driver. Such devices are ideally suited for the transportation of information, since they have no moving parts (e.g., more rugged than conventional micro drives), and are usually powered directly from the USB port (no external power or batteries). Although it should be noted that this “ultra” portability does have its own set of drawbacks, as will be outlined below.

While the aforementioned mass storage drive systems have the ability to deliver low-cost, data transportation to the masses, there are still a number of inherent limitations, which lead to a need for additional data integrity approaches, when operational continuity is required. Typically, conventional USB flash drives have been designed as “two-part” systems; 1) the flash memory drive itself 2) a detachable cover (e.g., acting as a protective cover for the USB connector “plug”). Since the cover itself is detachable, it can easily be lost, exposing the device's USB connector to foreign matter. Simply stated, dirt and other foreign matter increase the potential for shorts or inadvertent and intermittent breaks in the USB connection. This is especially true at front portion of the connector plug, where the connector pins themselves are located. These new external mass storage devices normally contain vital information (e.g., static registers, user data, etc.) in which a failure in the link between the memory drive and the host computer can be catastrophic.

In addition, these devices are typically connected “directly” into a host computer's USB port (e.g., no cable), and since many computer manufacturers are now stacking multiple USB ports together in very close proximity, the flash memory device, with it's larger than normal outside encasement, may not fit in the space provided (e.g., because of other USB cables and/or devices). In addition, it is known that some manufacturers “recess” their USB ports (e.g., USB ports on the “front” of a computer case), where again, the more oversized device may not fit into the space provided.

Problems such as those stated above, obviously, not only affect the system's continuity, but also creates much frustration with end-users.

All of this points to lost time and efficiencies, data integrity risks, and the real potential of losing critical data files.

Heretofore, a barrier has essentially existed for users to utilize a more “integrated” flash memory drive connector cover. There would be remarkable advantages in efficiencies and ease of use, if the current day two-piece drive systems were combined into a single integrated system, which may automatically retract.

As a result, a need exists in the art for an improved method and apparatus that provides the user with the ability to better protect against inadvertent connection breaks between a host computer and an external device.

A primary object of the present invention is to provide a new, novel and useful method and apparatus (e.g., a portable mass storage device), which protects “all” sides of common interface connector, and does not require the user to remove a separate connector cover before connecting a USB drive to a host computer.

A further object of the present invention is to provide an improved method for connecting a mass storage memory device (e.g. Flash, etc.) to a host computer, which has multiple USB ports in close proximity.

A still further object of the present invention is to provide an improved method and device as characterized above which by its nature is more simplified in operation, and thereby enhances the user's ease of use.

### SUMMARY OF INVENTION

A computer connector cover, comprising, in a preferred embodiment, a USB-based mass storage flash memory device, and an “integrated” cover (e.g., automatically retractable) for the USB connector portion; such that a user is not required to remove a “separate” connector plug cover, prior to insertion into a host computer's USB port.

The invention is distinguished over prior art connector systems in a multiplicity of ways. For one thing, the invention may use an integral cover, which automatically “retracts” when inserted into a USB port (e.g., spring loaded), or it may be achieved by manual means (e.g., a thumb actuated variable “slider” similar in nature to that of a utility knife, a sliding cover, etc.). Optionally, a safety release button may also be included. Equally as important, however, it gives the user a built-in dirt and dust cover (including an option for a front interface pin protector), heretofore unavailable, to better protect against intermittent USB connection breaks for use with today's more complex external devices.

It may also consist, for example, of a sliding internal carriage system to physically move and extend the USB connector sub-system out from the protective cover. Conversely, for example, the outer protective cover itself may slide, so as to reveal the USB connector plug.

With regard to the present invention, the value of the inventive device lies in the fact that “pocketable” devices by their nature are much more exposed to harsh environments in the “real-world”, when compared to the usage of prior art USB connectors, which tended to stay connected to a single computer.

In another embodiment, the standardized, more “narrow”, USB connector portion (e.g., 1 inch×1 inch×1 inch) may be extended (e.g., 1 inch×1 inch×3 inches, etc.), so to give it additional “clearance” room so as to more easily fit into a recessed USB port, or to better fit amongst, multiple, close proximity, USB ports and their associated cabling.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The present invention is illustrated by way of example and not by way of limitation in the figures of the accompanying drawings in which references indicate similar elements and in which:

FIG. 1 provides a perspective view of a typical prior art USB flash drive system.

FIG. 2 depicts a spring-loaded inner sleeve cover according to the present invention.

FIG. 3 provides a perspective view of a manually actuated cover, which retracts into the main housing.

FIG. 4 provides a perspective view wherein the outer encasement slides to reveal the connector and is depicted in the “retracted” position.

FIG. 5 provides a perspective view wherein the outer encasement slides to cover the connector and is depicted in the “protective” position.

FIG. 6 provides a block diagram of a sliding carriage embodiment in the retracted position.

FIG. 7 provides a block diagram of a sliding carriage embodiment in the extended position.

FIG. 8 provides a block diagram of a “long-throw” USB connector in a sliding carriage embodiment, and shown in the protective position.

FIG. 9 provides a perspective view wherein a detachable port extender is added to a conventional USB connector.

FIG. 10 provides a perspective view wherein the USB port is in a single, unified, extended configuration.

FIG. 11 depicts a swing-away front barrier protector door.

FIG. 12 provides a front perspective view wherein the connector has no front barrier protection.

FIG. 13 provides a front perspective view wherein the connector has the inventive front barrier protection.

### DETAILED DESCRIPTION

Before describing in detail the system in accordance with the present invention, it should be observed that the present invention resides primarily in what is effectively a novel combination of emerging memory circuits and integrated protective cover systems and components, and not in the particular detailed configurations thereof. Accordingly, the structure, control and arrangement of the circuits, covers, systems and components have been illustrated in the drawings by readily understandable diagrams which show only those specific details that are pertinent to the present invention, so as not to obscure the disclosure with structural details which will be readily apparent to those skilled in the art, having the benefit of the description herein. Thus, the diagram illustrations of the Figures do not necessarily represent all of the mechanical structural arrangements of the exemplary system, but are primarily intended to illustrate the major structural components of the system in a convenient functional grouping, whereby the present invention may be more readily understood. It is also important to understand that the invention is not limited in its application to the details of the construction illustrated and the steps described herein. The invention is capable of other embodiments and of being practiced or carried out in a variety of ways. It is to be understood that the phraseology and terminology employed herein is for the purpose of description and not of limitation.

While the preferred embodiment of the inventive device is generally shown and described as being incorporated in a USB flash memory mass storage device, it should be understood that the invention is not so limited, and is applicable to many external computer devices, and, in fact, aspects of the invention are applicable to other types of external computer devices, including but not limited to, Firewire and other device connectors.

For the purposes of this invention, the terms “intermittent” and “transient” are used interchangeably. The terms “inadvertent” or “intermittent” or “transient” with respect to a connection error, are used herein, with reference to a break in connectivity (e.g., power, data communication) between a host computer and an external device. The terms “engaged” and “retracted” with reference to position are used interchangeably, likewise, the terms “protective” and “extended” are also used interchangeably.

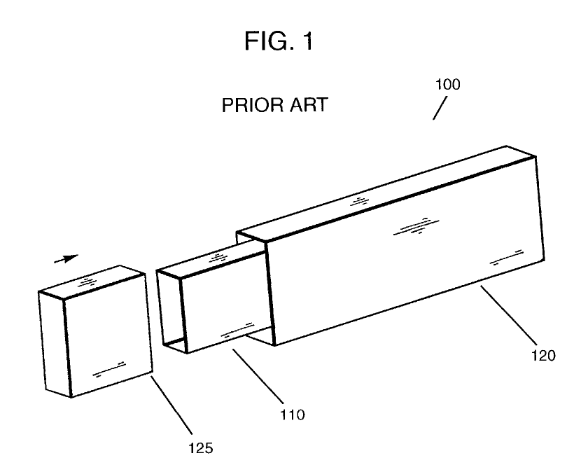

Referring now to the drawings, wherein like reference numerals indicate the same parts throughout the several views, a typical prior art device is shown in FIG. 1. Device 100 includes device component 120 (e.g., flash memory drive, wireless adapter, etc.), connector 110, such as, for example, USB (e.g., female), or Firewire, for communications with an external computer (not shown), and detachable connector cover 125.

An intermittent break of any duration whatsoever, in any of the USB wiring connections can cause present USB drivers to terminate the connection with remote device 100 and require the user to re-initialize the external device. Devices component 120, which may have static RAM or static memory registers (i.e., flash ram drives), which are much more affected by such connectivity problems, than other more simplified USB devices (e.g., keyboards). When USB devices lose power, they lose some or all of their configurations. When power is restored they will not work until the host computer re-initializes these registers and/or configurations. This process often requires operators'input or intervention and may also result in the loss of critical data files. Transient communication breaks are, of course, much more common if the connector sub-system (e.g., connector pins) contains dirt or other material, such as may be the case if a removable cover is lost, and the pocketable device connector is thereby left open and exposed to foreign matter.

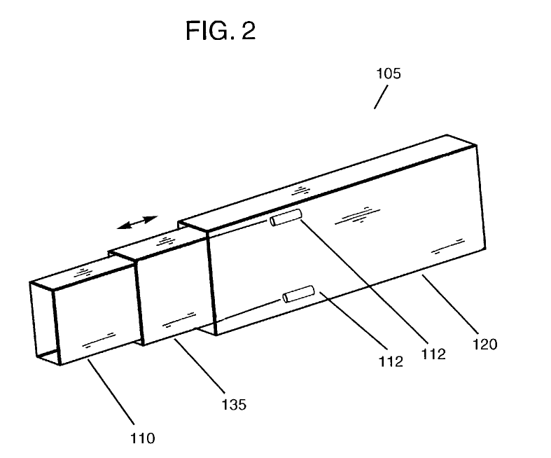

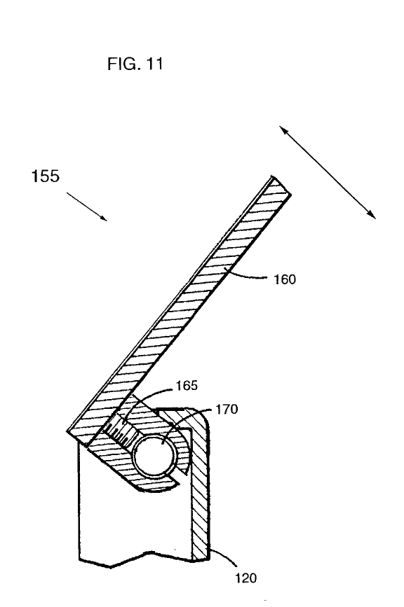

Referring now to FIG. 2, the system is illustrated in accordance with the present invention. External device 105 has connector cover 135, which is integrated directly with device component 120 (e.g., wherein cover 135 is in a inner sleeve configuration with respects to the outer encasement of device component 120). In this preferred integral embodiment, cover 135 may retract directly into the encasement of device 105. A front barrier protector (e.g., door 160 on FIG. 11) may also be utilized so as to protect connector 110 when cover 135 is in the protective position. Device 105 may include an automatic extension/retraction feature for cover 135 (e.g., by utilizing springs 112, or the like). Going into more detail, protective cover 135 may be slightly larger than the corresponding USB port itself (on the host computer), and as device 105 is mated to the USB port, cover 135 would stop at the opening of the port, and connector 110 would then extend out from cover 135 to allow full connection to the current host computer.

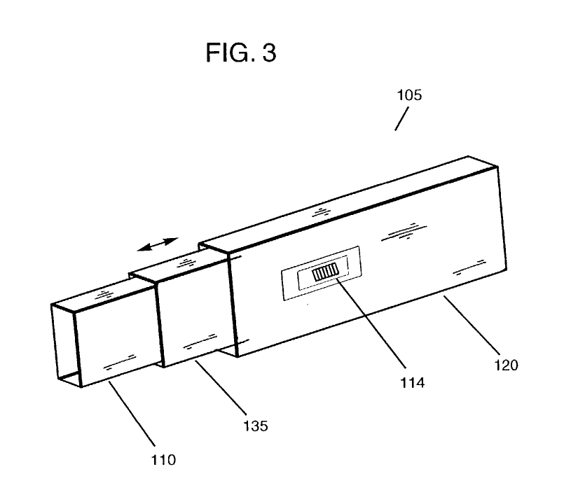

Referring next to FIG. 3: As will be apparent to those skilled in the art, manual extender 114 may be used to move retractable cover 135, using, for example, a slider system, a roller system, etc. If the slider configuration is used to extend and retract inner sleeve cover 135, it may be similar in nature to that often used with utility knives, razors, scrapers, and the like. U.S. Pat. No. 5,806,189, Bailey, entitled “Utility knife”, and U.S. Pat. No. 5,813,121, Gringer, entitled “Automatically retractable utility knife” are hereby incorporated herein by reference, in their entirety, including all Figure drawings. By way of example and not limitation, if manual extender 114 is embodied as a roller system, it may employ a “geared” approach (e.g., a notched male roller wheel, which mates to corresponding females notches on cover 135). Alternatively, the roller system may be solely friction-based system. Here again, (and in the following embodiments) front barrier protector 160 (shown on FIG. 11) may be attached to the front end of cover 135, and be utilized so as to protect connector 110 when cover 135 is in the protective position.

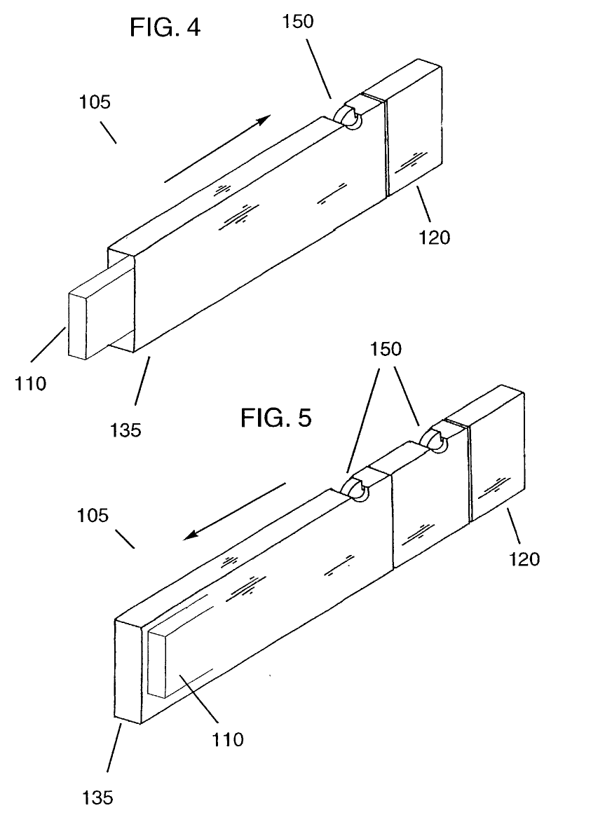

Moving on to FIGS. 4 and 5: In another embodiment, device 105 may have an outer protective cover which itself may slide, so as to reveal connector plug 110. As will be apparent to those skilled in the art, device component 120 would be enclosed in protective cover 135 in which at least a portion of the device cover would “slide”. FIG. 4 depicts cover 135 in the “retracted” position, wherein sliding cover 135 allows connector 110 to be exposed when desired. Optionally, this device may have a manually actuated safety release 150 which until pressed (e.g., inwards) would not allow the protective cover to retract and/or extend. Of course, release 150 may take other forms as is well known in the art, such as, for example, a push button release system, a ball and receiver system, etc. FIG. 5 depicts cover 135 in the “extended” position, thereby providing protection for connector 110.

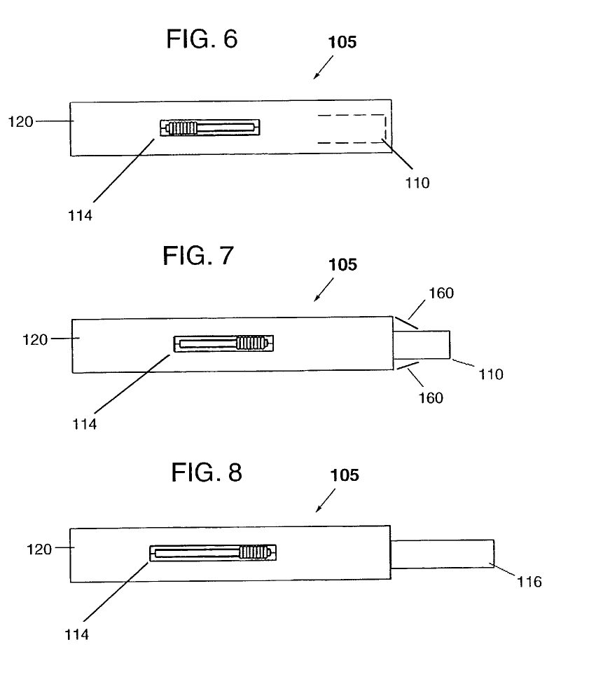

Referring next to FIGS. 6 and 7: In this embodiment of the inventive device, a sliding internal carriage system may be utilized to physically move and extend connector 110 out from the protective encasement of device component 120. Here again, the basic action may be similar in nature to that often used with utility knives, razors, scrapers, and the like. Manual extender 114 (as shown in FIG. 6) is in the retracted position, and as it is moved forward as shown in FIG. 7, connector 110 is shifted outwards and revealed. The sliding action may optionally be initiated by first pressing a safety release button or the like. This embodiment, with its ability to retract into the housing, can offer the advantage of an overall smaller footprint when compared to prior art devices (e.g., FIG. 1, the '500 patent). This, obviously, is extremely important feature for a pocketable device. In addition, front barrier protector 160 (e.g., door(s)) are shown in FIG.11). Manual extender 114 may, for example, be mounted on the top or on a side of the encasement for device 105.

Referring next to FIG. 8: In this embodiment of the inventive device 105, USB connector 110 is shown in it's “long-throw” extended configuration. As used herein, the term long-throw means being substantially longer than specified in the existing standard for a peculiar connector. By way of non-limiting example, conventional USB connectors are approximately ¼″ H×1″ W×1″ L, in the inventive device the length may be extended anywhere from 15% percent, upwards to 200%, or more, so as to give connector 110 additional “clearance” room so as to more easily fit into a recessed USB port, or to better fit amongst, multiple, close proximity, USB ports and their associated cabling.

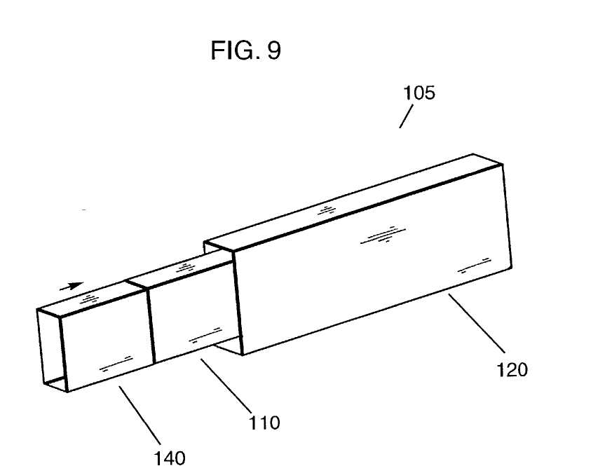

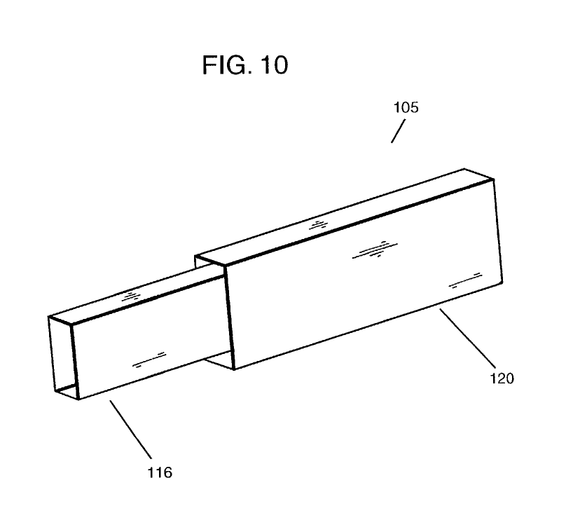

Moving on to FIG. 9: In a further embodiment generally similar to FIG. 8, a −separate” male to female port extension 140 is added to connector 110, so as to give additional distance (e.g., 2 inches) away from the housing of device component 120, which can be required by larger bodied USB devices. This extension could be a “solid” monolithic structure, vs. conventional male and female connectors connected by a “flexible” cable. By way of non-limiting example, extension 140 may house a male USB connector at it's rear portion for connection to connector 110 and extension 140 may house a female USB connector at the front portion for connection to a host computer. Extension 140 may be put into commercial usage with or without integrated cover 135. The design of extension 140 can be accomplished by one ordinarily skilled in the art.

With reference to FIG. 10, device 105 is depicted in a single, “unified” (e.g., non-detactable), “long-throw” embodiment, similar in nature to that as shown in FIG. 9.

Referring now to FIG. 11, device component 120 may have protective front barrier assembly 155, that when actuated, may reveal the USB connector through protective barrier 160, such as a door or a flexible diaphragm, etc. The door(s) may swing out (e.g., using hinge 170) of the path of connector 110 and may be spring loaded (e.g., using spring 165) so as to automatically close when the operation is reversed. The flexible diaphragm 160 embodiment may have a small slit 185 which would allow the USB connector to push through when manually actuated. It is important to note that the aforementioned '500 patent makes no attempted to address the issue of a front protector. By way of example and not limitation, other examples of suitable covers 135 may be a hinged cover, a flip away cover, an inter-connected cover system (e.g., a cable or other means integrating the device 100 and protective cover 110 together) and other similar approaches. The connector and/or plug may be designed so as to be “inter-locking” with the host port, so as to better prevent against inadvertent connection breaks. Door 160 may have to be slightly recessed into cover 135 for the automatic retraction embodiment (e.g., FIG. 2). Such embodiments as described above may be incorporation into the current invention by one skilled in the art, having the benefit of the disclosure contained herein.

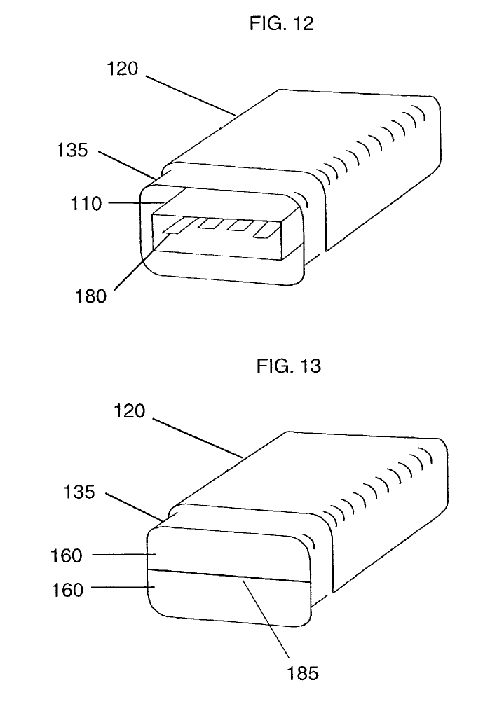

With reference to FIG. 12, a front view including connector 110, cover 135, and connector pins 180 are shown. FIG. 13 is similar to FIG. 12 with the addition of front protective barrier 160.

Regarding device component 120 itself, if it is embodied as a memory device, it may be, for example: a memory card; a memory cartridge; a removable hard disk; a mass data storage device, a flash memory device; flash drive card; a micro-drive; or the like. Alternatively, device component 120 may be, for example, a wireless adapter (i.e., Bluetooth®, ultra-wideband, etc.), a barcode identifier and/or scanner, a RF transceiver, an identification interface (e.g., such as Mobil's® Speed Pass, fingerprint 118 and/or iris acquisition scanner, etc.), an electronic voice recorder, a music jukebox (e.g., MP3), a geo-location system (i.e., GPS), and other external device systems.

The inventive device also has applications for general-purpose USB connectors (e.g., attached to either a male or female USB plug, with or without a flexible cable, etc.) and may also be integrated in other types of connector plugs (e.g., cell phone, personal electronics, etc.).

While the present invention has been described with reference to specific exemplary embodiments, it will be apparent to those skilled in the art that various modifications and changes may be made to these embodiments without departing from the broader spirit and scope of the invention as set forth in the claims. Since modifications of the disclosed embodiments incorporating the spirit and substance of the invention may occur to persons skilled in the art, the invention should be construed to include everything within the scope of the appended claims and equivalents thereof. Accordingly, the specification and drawings are to be regarded in an illustrative rather than restrictive sense.

1) an external computer device with a standard interface comprising;
a housing;
a standardized connector for connecting to a computer; and
a spring-loaded cover integral with said housing, wherein said cover has a protective position and an engaged position, such that when said cover is in said protective position, said connector is covered by said cover, and when said cover is in said engaged position said connector is exposed from said cover.

2) The external computer device of claim 1, wherein said standardized connector comprises a universal serial bus.

3) The external computer device of claim 1, wherein said standardized connector comprises an IEEE-1394 bus.

4) The external computer device of claim 1, wherein said external computer device is a mass storage memory device.

5) The external computer device of claim 1, wherein said external computer device is a flash RAM drive.

6) The external computer device of claim 1, wherein said external computer device is selected from the list consisting of at least one of the following:
a)a wireless adapter;
b)a barcode scanner;
c)a RF transceiver;
d)an identification interface;
e)an electronic voice recorder;
f)a music jukebox; and
g)a geo-location system.

7) An external computer device with a standard interface comprising: a) a housing; b) memory contained within said housing; c) a standardized connector for connecting to a computer; d) a retractable cover including a front barrier protector, integral with said housing, wherein said cover has a protective position and an engaged position, such that when said cover is in said protective position, said connector is covered by said cover, and when said cover is in said engaged position said connector is exposed from said cover.

8) The external computer device of claim 7, wherein said standardized connector comprises a universal serial bus.

9) The external computer device of claim 7, wherein said standardized connector comprises an IEEE-1394 bus.

10) The external computer device of claim 7, wherein said memory is a mass storage device.

11) The external computer device of claim 7, wherein said memory is a flash RAM.

12) The external computer device of claim 7, wherein said external computer device is selected from the list consisting of at least one of the following:
a) a wireless adapter;
b) a barcode scanner;
c) a RF transceiver;
d) an identification interface;
e) an electronic voice recorder;
f) a music jukebox; and
g) a geo-location system.

13) An external computer device with a standard interface comprising;
a housing;
a standardized connector for connecting to a computer; and
an inner sleeve body integral with said housing, wherein said inner sleeve has a protective position and an engaged position, such that when said inner sleeve is in said protective position, said connector is covered by said inner sleeve, and when said cover is in said engaged position said connector is exposed from said inner sleeve.

14) The external computer device of claim 13, wherein said standardized connector comprises a universal serial bus.

15) The external computer device of claim 13, wherein said standardized connector comprises an IEEE-1394 bus.

16) The external computer device of claim 13, wherein said external computer device is a mass storage memory device.

17) The external computer device of claim 13, wherein said external computer device is a flash ram drive.

18) The external computer device of claim 13, wherein said external computer device is selected from the list consisting of at least one of the following:
h)a wireless adapter;
i)a barcode scanner;
j)a RF transceiver;
k)an identification interface;
l)an electronic voice recorder;
m)a music jukebox; and
n)a geo-location system.

19) An external computer device with a standard interface comprising:
a housing; and
a standardized connector for connecting to a computer, wherein said connector is disposed on a slideable carriage, such that it is retractable within said housing.

20) The external computer device of claim 19, wherein said standardized connector comprises a universal serial bus.

21) The external computer device of claim 19, wherein said standardized connector comprises an IEEE-1394 bus.

22) The external computer device of claim 19, wherein said external computer device is a mass storage memory device.

23) The external computer device of claim 19, wherein said external computer device is a flash ram drive.

24) The external computer device of claim 19, wherein said external computer device is selected from the list consisting of at least one of the following:
a) a wireless adapter;
b) a barcode scanner;
c) a RF transceiver;
d) an identification interface;
e) an electronic voice recorder;
f) a music jukebox; and
g) a geo-location system.

25) An external computer device comprising a standardized connector in communication with said external device for connecting to a computer, wherein said standardized connector is in a long-throw configuration.

26) The external computer device of claim 25, wherein said standardized connector comprises a universal serial bus.

27) The external computer device of claim 25, wherein said standardized connector comprises an IEEE-1394 bus.

28) The external computer device of claim 25, wherein said external computer device is a mass storage memory device.

29) The external computer device of claim 25, wherein said external computer device is a flash ram drive.

30) A port extender comprising;
a housing;
a male USB connector; and
a female USB connector, wherein said male USB connector and said female USB connector are contained within said housing.

31) The port extender of claim 31, wherein said housing consists of a rigid material.
